(19) United States
(12) Patent Application Publication
(10) Pub. No.: US 2024/0370698 A1
(43) Pub. Date: Nov. 7, 2024

(54) INFORMATION PROCESSING APPARATUS, AND RECORDING MEDIUM

(71) Applicant: THE UNIVERSITY OF TOKYO, Tokyo (JP)

(72) Inventors: Atsutake KOSUGE, Tokyo (JP); Tadahiro KURODA, Tokyo (JP)

(73) Assignee: THE UNIVERSITY OF TOKYO, Tokyo (JP)

(21) Appl. No.: 18/686,072

(22) PCT Filed: Aug. 24, 2022
(86) PCT No.: PCT/JP2022/031945

§ 371 Date: Feb. 23, 2024

(30) Foreign Application Priority Data
Aug. 26, 2021 (JP) 2021-138412

(51) Int. Cl. G06N 3/045

(52) U.S. Cl. CPC G06N 3/045

(57) ABSTRACT

An information processing apparatus receives an input of a machine learning parameter for a first-type neural network which has machine-learned an output corresponding to a predetermined input, and transforms the received machine learning parameter to a machine learning parameter for a second-type neural network which is a different type neural network from the first-type neural network. On the basis of the transformed machine learning parameter, the information processing apparatus generates production information for producing the second-type neural network, and generates estimate information regarding at least one of a scale and performance, relating to the second-type neural network produced in accordance with the production information.

### TECHNICAL FIELD

The present disclosure relates to an information processing apparatus, and a recording medium.

### BACKGROUND ART

Neural network circuits have been recently researched, and some of them use a circuit which performs operations of multiplying a corresponding weight to each of a plurality of input signals, accumulating the weight-multiplied results, and outputting after performing nonlinear transformation with an activation function. This circuit is a circuit which imitates a neuron. In the neural network circuit using such circuits, a plurality of the circuits are mutually connected to perform machine leaning.

In this example, the above-mentioned weight and the connection between the circuits imitating a neuron are machine-learned. However, the costs for storing and reading the weights, and for product-sum calculation of the input signals are large, and thus, various methods for efficient machine learning have been researched (Song Han, et al., Learning both Weights and Connections for Efficient Neural Networks, Advances in Neural Information Processing Systems, Vol. 28, 2015 (arXiv: 1506.02626)).

### SUMMARY

### Problems to be Solved

As above, conventionally, when a neural network circuit is produced, there are various matters which should be considered, such as efficiency of the machine learning, optimization of the circuit design, and the like. Currently, trials in designs and machine learning processes are repeated to improve the performance, and thus, improvement of the design efficiency is a problem to be solved.

The present disclosure has been made in view of the above. One of the objectives of the present disclosure is to provide an information processing apparatus and a recording medium capable of improving the efficiency of the neural network circuit design.

### Solving Means

One aspect of the present disclosure for solving the drawbacks of the above conventional examples is an information processing apparatus comprising: a receiving device which receives an input of a machine learning parameter for a first-type neural network which has machine-learned an output corresponding to a predetermined input; a transformation processing device which transforms the received machine learning parameter for the first-type neural network to a machine learning parameter for a second-type neural network which is a different type neural network from the first-type neural network; a generation device which generates production information for producing the second-type neural network, on the basis of the transformed machine learning parameter; an estimation device which generates estimate information regarding at least one of a scale and performance, relating to the second-type neural network produced in accordance with the production information; and an output device which outputs the production information and the estimate information.

### Effect of Disclosure

According to the present disclosure, machine learning parameters of a new neural network can be obtained by transforming machine learning parameters of another type neural network which has already been machine learned, and estimate information regarding the scale, performance, etc., of the new neural network can be generated and output, resulting in contributing the improvement of the efficient designing of a neural network circuit

### DETAILED DESCRIPTION OF DRAWINGS

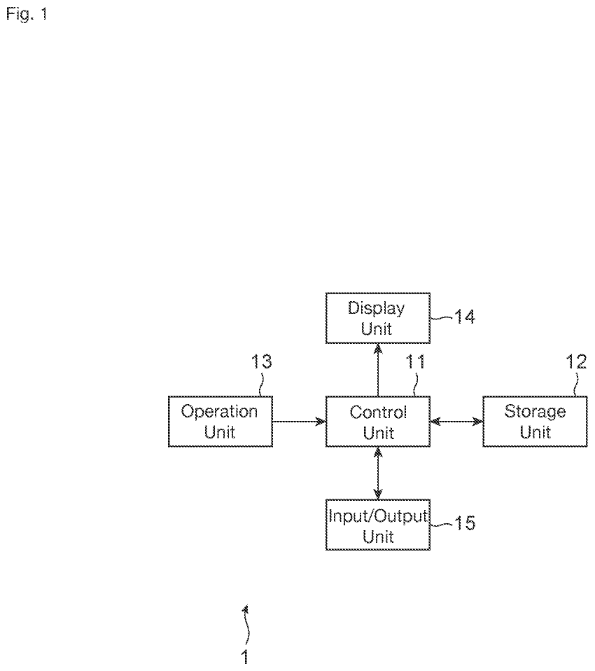

FIG. 1 is a block diagram illustrating a configuration example of an information processing apparatus according to an aspect of the present disclosure.

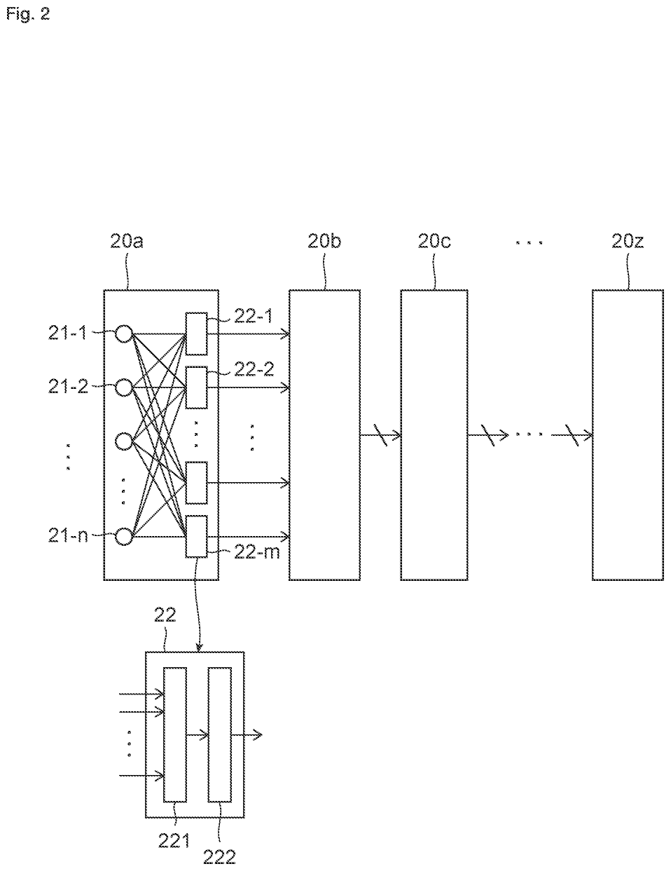

FIG. 2 is an explanatory view illustrating an example of a first-type neural network to be processed by an information processing apparatus according to an aspect of the present disclosure.

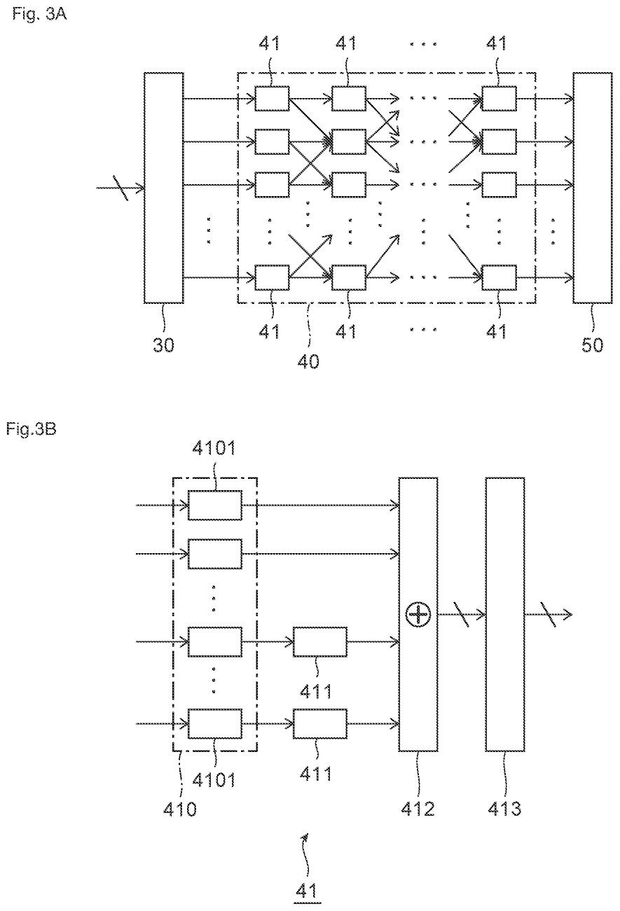

FIG. 3A is an explanatory view illustrating an example of a second-type neural network to be generated by an information processing apparatus according to an aspect of the present disclosure.

FIG. 3B is an explanatory view illustrating an example of a second-type neural network to be generated by an information processing apparatus according to an aspect of the present disclosure.

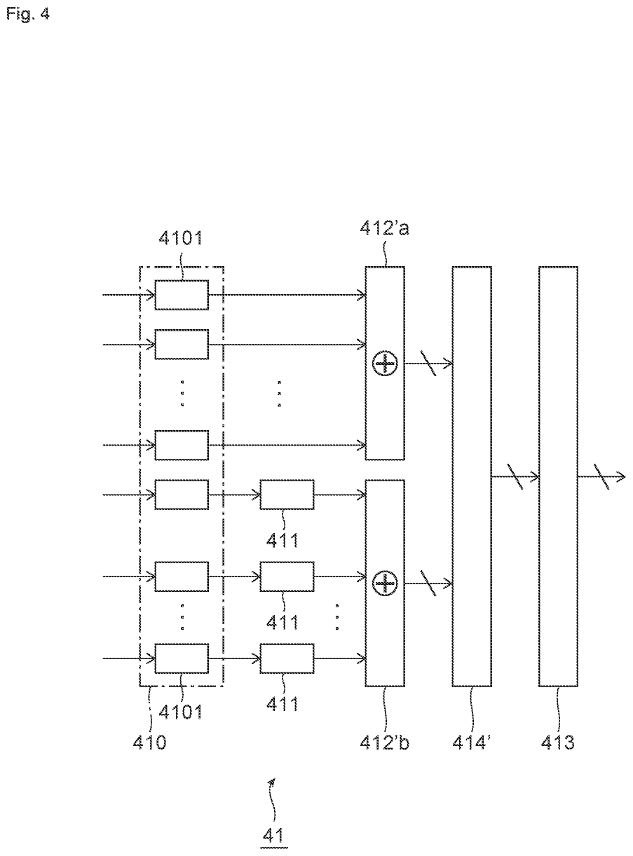

FIG. 4 is an explanatory view illustrating another example of a second-type neural network to be generated by an information processing apparatus according to an aspect of the present disclosure.

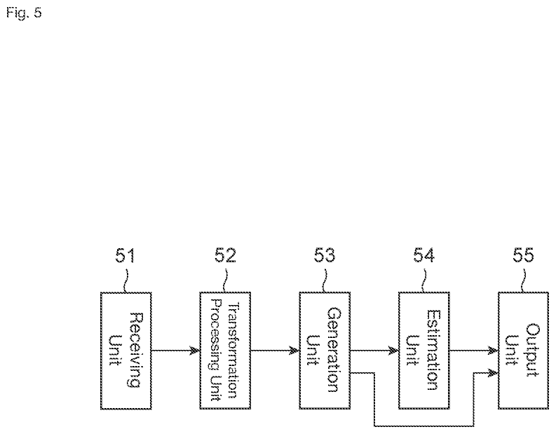

FIG. 5 is a functional block diagram illustrating an example of an information processing apparatus according to an aspect of the present disclosure.

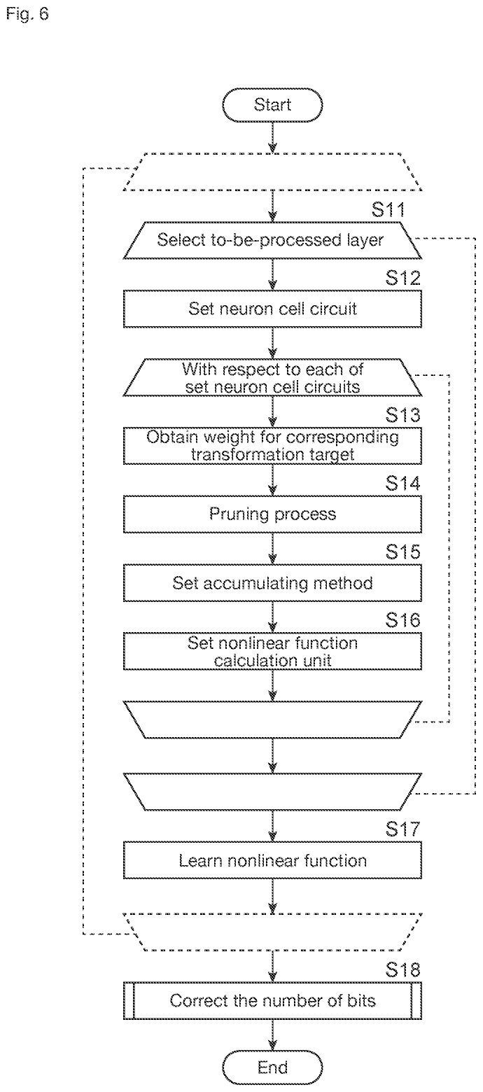

FIG. 6 is a flowchart illustrating an operational example of an information processing apparatus according to an aspect of the present disclosure.

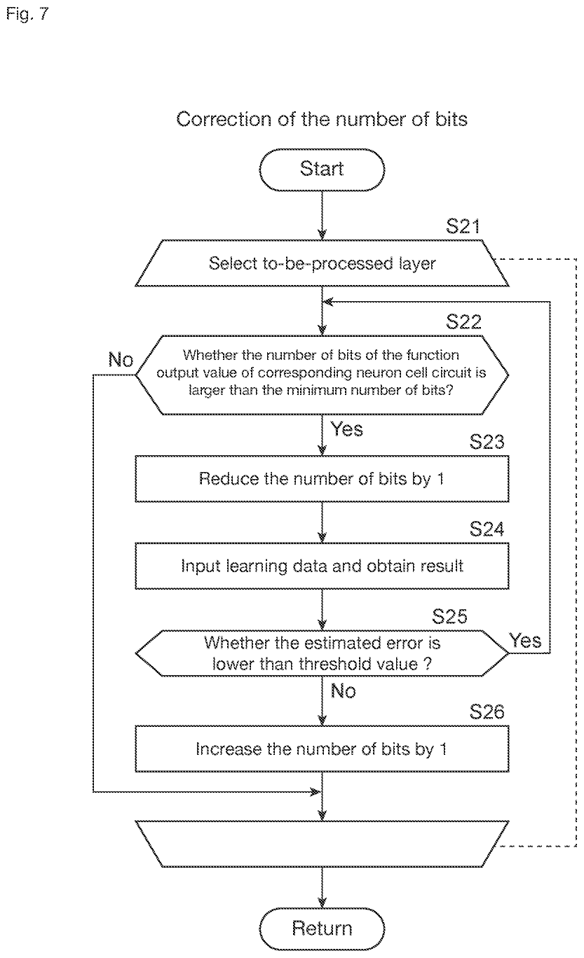

FIG. 7 is another flowchart illustrating an operational example of an information processing apparatus according to an aspect of the present disclosure.

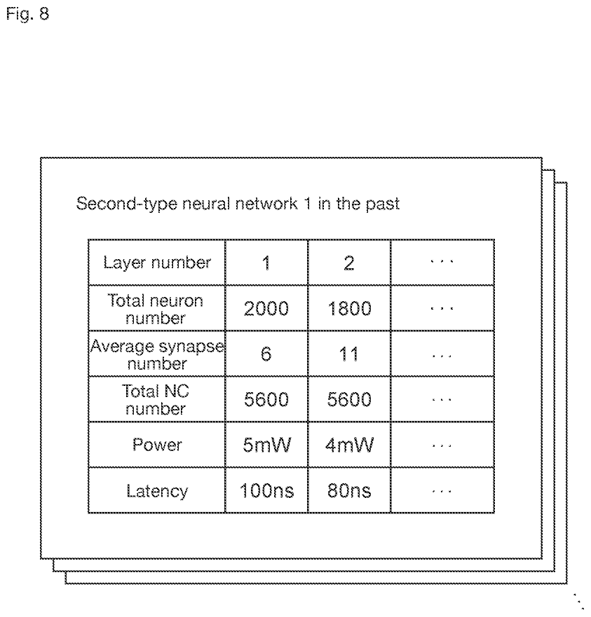

FIG. 8 is an explanatory view illustrating a content example of a result database used by an information processing apparatus according to an aspect of the present disclosure.

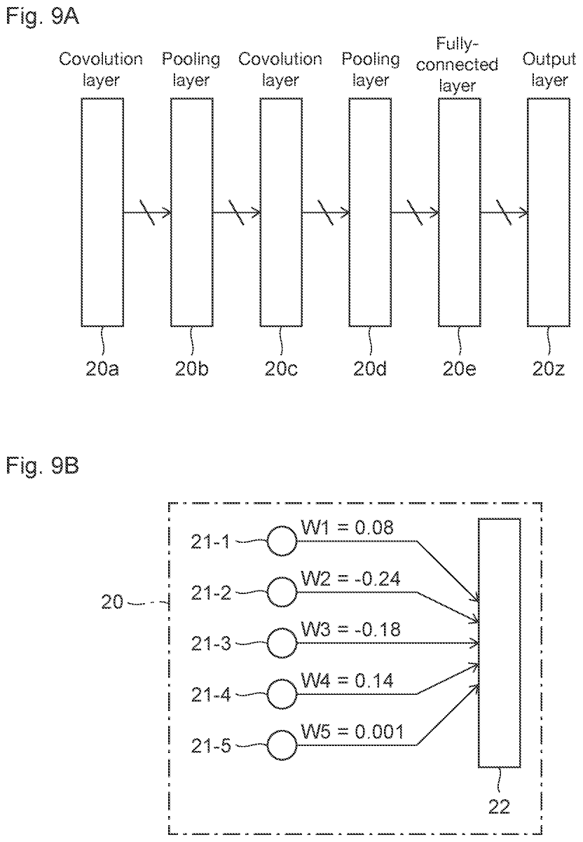

FIG. 9A is an explanatory view illustrating an example of a first-type neural network to be processed in an operational example of an information processing apparatus according to an aspect of the present disclosure.

FIG. 9B is an explanatory view illustrating an example of a first-type neural network to be processed in an operational example of an information processing apparatus according to an aspect of the present disclosure.

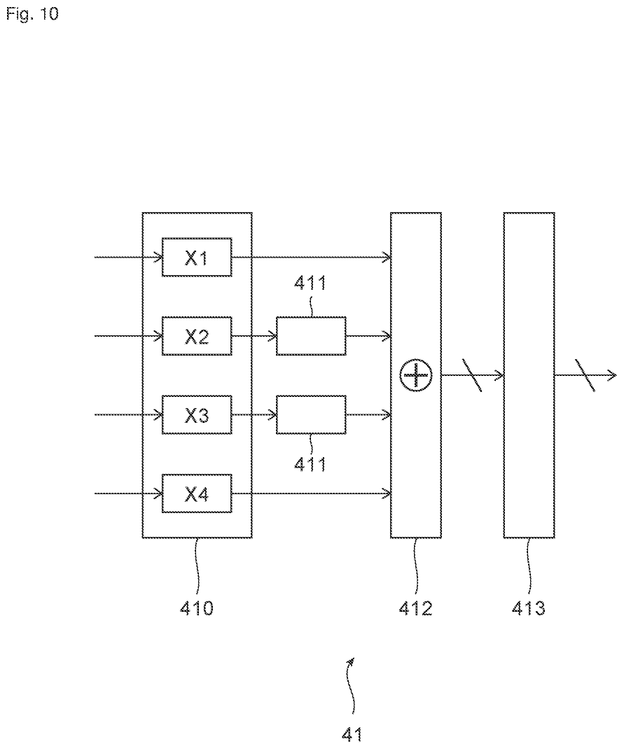

FIG. 10 is an explanatory view illustrating and example of a neuron cell circuit of a second-type neural network to be generated in an operational example of an information processing apparatus according to an aspect of the present disclosure.

### Aspects of Disclosure

Aspects of the present disclosure will be explained with reference to the drawings. As exemplified in FIG. 1, an information processing apparatus 1 according to an aspect of the present disclosure comprises a control unit 11, a storage unit 12, an operation unit 13, a display unit 14, and an input/output unit 15.

The control unit 11 is a program-controlled device such as a CPU, and operates in accordance with a program stored in the storage unit 12. According to an example of the present aspect, the control unit 11 receives an input of a machine learning parameter of a first-type neural network which has machine-learned output information corresponding to predetermined input information. Here, the first-type neural network is, for example, a deep learning neural network which, as exemplified in FIG. 2, comprises a neural network having an input layer 20a, at least one intermediate layer 20b, c, . . . , and an output layer 20z.

Further, as exemplified in FIG. 2, each layer of the neural network has input nodes 21-1, 21-2 . . . , 21-n, and output nodes 22-1, 22-2 . . . , 22-m. Each output node 22 (when distinguishing each of the output nodes 22-1, 22-2 . . . is not necessary, the suffix −1, −2 . . . is omitted to merely describe as the output node 22) includes a product-sum calculation unit 221 and a nonlinear function calculation unit 222. The product-sum calculation unit 221 of the i-th (i=1, 2, . . . , m) output node 22-i uses a weight wij (j=1, 2, . . . , n) set by machine learning and bias b, to perform accumulation by multiplying a corresponding weight wij to each input value xj (j=1, 2, . . . , n) from the input node 21-1, 21-2 . . . , respectively, and perform addition of the bias b to the accumulation result.

The nonlinear function calculation unit 222 receives an input of the calculation result of the product-sum calculation unit 221 as an input to a predetermined nonlinear function (for example, a sigmoid function, etc.), obtains an output value of the nonlinear function, and outputs the obtained output value. This output value is to be input to the input node 21 of the neural network of the next layer, or to be output to the outside (in case that the output value is output from the final layer having no next layer).

The control unit 11 transforms the received machine learning parameters (the weight wij, the bias b, etc., of each neural network) of the first-type neural network, to machine learning parameters of a second-type neural network which is different from the first-type neural network. An example of the specific configuration of the second-type neural network will be described layer.

On the basis of the machine learning parameters obtained by the transformation, the control unit 11 generates production information for producing the second-type neural network. As an example, the production information is described by a hardware description language such as VHDL (Verilog Hardware Description Language), etc. In this example, the production information expresses what the hardware of the second-type neural network is like. The production information of this example, the expression of the hardware thereby, and the hardware production method based on this production information, are widely known. Thus, explanation therefor is omitted here.

Further, the control unit 11 generates estimate information regarding at least one of scale and performance of the second-type neural network produced in accordance with the production information, and outputs the production information and the estimate information. Detailed content of the operation of this control unit 11 will be explained later.

The storage unit 12 is a memory device, a disk device, etc., which stores a program to be executed by the control unit 11. Further, the storage unit 12 also operates as a work memory of the control unit 11. The program may be provided by being stored in a computer readable and non-transitory storage medium and installed in the storage unit 12.

The operation unit 13 includes a mouse, a keyboard, etc., receives an operation by a user, and outputs information representing the content of the operation to the control unit 11.

The display unit 14 includes, for example, a display, etc., and outputs information in accordance with instructions input from the control unit 11.

The input/output unit 15 is an interface such as a USB (Universal Serial Bus), etc., which receives information from the outside such as machine learning parameters of the first-type neural network, etc., and outputs the received information to the control unit 11. Further, the input/output unit 15 information outputs information to the external apparatus in accordance with the instructions input from the control unit 11. Further, the input/output unit 15 receives data from an external storage apparatus, and outputs the received data to the control unit 11.

Here, an example of the second-type neural network is to be explained. In the present aspect, as exemplified in FIG. 3A, an example of the second-type neural network comprises an input circuit unit 30, at least one machine learning circuit 40, and an output circuit unit 50. Here, the machine learning circuit 40 further comprises at least one neuron cell circuit (NC) 41. The neuron cell circuit 41 comprises at least one input unit 410, an adder unit 412 accumulating the input data, and a nonlinear function calculation unit 413, and, in a predetermined case explained below, further comprises an inverter 411 which inverts the sign of the input data and outputs the inverted data.

As exemplified in FIG. 3B, specifically, the input unit 410 has at least one input port 4101, and receives input data through each input port 4101. The input unit 410 outputs the data input from each input port 4101 directly to the adder unit 412, or outputs the data through the inverter 411 to the adder unit 412. Then, the adder unit 412 accumulates the data directly input from each input port 4101 of the input unit 410, or the sign-inverted data input through the inverter 411.

The nonlinear function calculation unit 413 receives an input of an accumulated value of the data accumulated and output by the adder unit 412, and outputs a calculation result of a predetermined nonlinear function corresponding to the input. Further, the nonlinear function calculation unit 413 of this example outputs a calculation result of a predetermined nonlinear function regarding a value obtained by multiplying a predetermined weight value to the accumulated value output from the adder unit 412. The nonlinear function calculation unit 413 may be formed by a predetermined calculator, or may be formed by using a nonvolatile memory device such as ROM, as described below.

Namely, an example of this nonlinear function calculation unit 413 is a nonvolatile memory device having a memory address “a” storing a value A·f (a·Δq) which is obtained by multiplying a weight information A (A being a predetermined positive real number value) by a value f (a·Δq) which is an output value of the predetermined nonlinear function f corresponding the input value q(=a·Δq).

Here, Δq is obtained by:

$$Δ q = ( x max - x min ) / ( V max - V min )$$

wherein, Vmax is a maximum value that the adder unit 412 can output, Vmin is a minimum value that the adder unit 412 can output, and xmin and xmax are domains of the function f (with the proviso that xmin<xmax is satisfied). Calculation of Δq is not limited to the above. As far as a value between the above domain is input, and in response, a value of the nonlinear function f corresponding to the input value is output, other calculation method can be used for determining Δq. Alternatively, the domain xmin and the domain xmax of the function f may be set to satisfy Δq=1.

In the second-type neural network of this example, machine learning parameters are an accumulation method of the data output from each input port 4101 of the input unit 410 (the outputs from which input port 4101 are sign-inverted and accumulated, and the like), and the nonlinear function calculated by the nonlinear function calculation unit 413 (in case of the above example, corresponding to a value stored in each address of the memory device).

Further, the neuron cell circuit 41 of the second-type neural network is not limited to the above. For example, as exemplified in FIG. 4, the neuron cell circuit 41 may comprise an input unit 410, a pair of adder units 412′a and 412′b, a multiplication-addition unit 414 for multiplying a weight, and a nonlinear function calculation unit 413′, and in a predetermined case explained below, may further comprise an inverter 411 which invers the sign of data received by the input unit 410. Here, the same numerical value is assigned to the same structure shown in FIGS. 3A and 3B.

In this example of FIG. 4, the input unit 410 also outputs the data input from each input port 4101 directly to the adder unit 412′a, or outputs the data through the inverter 411 to the adder unit 412′b. The adder unit 412′a accumulates the data directly output by the input unit 410, and outputs an accumulated value of data (conveniently, referred to as P-data) which is to be multiplied by a positive weight. The adder unit 412′b accumulates the sign-inverted data output by the input unit 410 through the inverter 411, and outputs an accumulated value of data (conveniently, referred to as N-data) which is to be multiplied by a negative weight.

The multiplication-addition unit 414 multiplies the P-data output from the adder unit 412′a, by a predetermined weight value Wp (here, Wp is a positive real number value). Also, the multiplication-addition unit 414 multiplies the N-data output from the adder unit 412′b, by a predetermined weight value Wn (here, Wn is a positive real number value, and may be the same as Wp or may be different from Wp). Then, the multiplication-addition unit 414 adds the value obtained by multiplying the P-data by the weight value Wp, to the value obtained by multiplying the N-data by the weight value Wn, and outputs the result of the addition.

The nonlinear function calculation unit 413′ receives an input of the value output from the multiplication-addition unit 414, and outputs a calculation result of a predetermined nonlinear function corresponding to the input. The nonlinear function calculation unit 413′ may also be formed by a predetermined calculator, or may be formed by using a nonvolatile memory device such as ROM, as described below.

In this example, the nonlinear function calculation unit 413′ is a nonvolatile memory device having a memory address “a” storing a value f (a Δq) which is an output value of the predetermined nonlinear function f corresponding the input value q(=a·Δq).

Here, Δq is obtained by:

$$Δ q = ( x max - x min ) / ( V max - V min )$$

wherein, Vmax is a maximum value that the multiplication-addition unit 414 can output, Vmin is a minimum value that multiplication-addition unit 414 can output, and xmin and xmax are domains of the function f (with the proviso that xmin<xmax is satisfied). Calculation of Δq is not limited to the above. As far as a value between the above domain is input, and in response, a value of the nonlinear function f corresponding to the input value is output, other calculation method can be used for determining Δq. Alternatively, the domain xmin and the domain xmax of the function f may be set to satisfy Δq=1.

Next, operations of the control unit 11 according to an aspect of the present disclosure are to be explained. As exemplified in FIG. 5, in an example of the present aspect, the control unit 11 operates in accordance with the program stored in the storage unit 12, and functionally has a configuration comprising a receiving unit 51, a transformation processing unit 52, a generation unit 53, an estimation unit 54, and an output unit 55.

The receiving unit 51 receives an input of a machine learning parameter of the first-type neural network which is to be processed. Here, for the purpose of explanation, specifically, the input is a learning parameter of a deep learning neural network which has machine-learned the output corresponding to a predetermined input.

The transformation processing unit 52 transforms the machine learning parameter of the first-type neural network which has been received by the receiving unit 51 to a machine learning parameter of the second-type neural network. According to an example of the present aspect, the transformation processing unit 52 uses a separately input learning data, in addition to the machine learning parameter of the first-type neural network received by the receiving unit 51, for obtaining the machine learning parameter of the second-type neural network.

This learning data may be a set of input data and output data (training data) which should be output by the second-type neural network in response to the input data.

Further, in case that the second-type neural network is the one exemplified in FIGS. 3A and 3B, the transformation processing unit 52 refers to the learning parameter of the deep learning neural network received by the receiving unit 51, and generates production information for configuring each neuron cell circuit 41.

Specifically, as exemplified in FIG. 6, regarding the first-type neural network received by the receiving unit 51, the transformation processing unit 52 sequentially selects each of the layers of the first-type neural network starting from the input layer 20a, so that the layer is selected from the closest to the furthest, as a layer to be processed (S11: Selection of to-be-processed layer). The transformation processing unit 52 virtually generates and initializes at least one neuron cell circuit 41 corresponding to an output node 22-j (j=1, 2 . . . , m) of the selected to-be-processed layer (S12). The transformation processing unit 52 sequentially selects the virtually generated neuron cell circuits 41, and obtains a weight value for each input node 21-1, 21-2 . . . , 21-n connected to the output node 22-j corresponding to the selected neuron cell circuit 41 (S13).

The transformation processing unit 52 refers to the weight value for each input node 21-1, 21-2 . . . , 21-n connected to each output node 22-j in the first-type neural network, and performs a pruning process. For example, on the basis of the absolute value of the weight value that has been referred to, the transformation processing unit 52 excludes the input node with a weight value below a predetermined threshold value, and virtually generates an input port 4101 corresponding to the input node 21 with a weight value exceeding the threshold value (S14: pruning process). As explained above, the threshold value used here can be set, for example, by a user. Further, the threshold value of the weight value can be determined by excluding the input node with a weight value that falls into a predetermined ratio from the lowest, in the distribution of weight values of the respective input nodes 21 that have been referred to. For example, when the input nodes in the lowest 20% (the ratio can also be set by a user) are excluded, the minimum weight value among the weight values for the input nodes 21 that have not been excluded, may be determined as a threshold value. Furthermore, a different threshold value can be set for each to-be-processed layer, in view of the position of the to-be-processed layer (positional relationship relative to a predetermined layer such as the input layer, output layer, etc.) in the first-type neural network.

Further, as an example, the threshold values, etc., of this pruning process may be set so that the minimum threshold value is set for the last layer before the layer right before the output layer. Thereby, for example, in the case that a deep learning neural network where a fully-connected layer is arranged one before the output layer, is transformed to obtain a second-type neural network, in the neuron cell circuit 41 corresponding to a layer closer to the fully-connected layer (the fully-connected layer is excluded), a larger number of input ports 4101 are removed.

Further, in general, in case that the first-type neural network is a deep learning neural network having an input layer as the first layer, and an output layer as the N-th layer (N being an integer of 3 or more), the transformation processing unit 52 may determine the threshold value, etc., of the pruning process as below. Namely, when the neuron cell circuit 41 is set corresponding to the output node of the i-th layer (i being an integer satisfying 1≤i≤N) of the first-type neural network layer, the transformation processing unit 52 may control so that, as far as the value “i” representing the depth of the layer is equal to or lower than at least a predetermined integer value J (with the proviso, 1<J≤N), the larger the value “i” representing the layer depth, the smaller the number of input ports set by the pruning process (for example, the larger the threshold value).

The transformation processing unit 52 sets a virtual adder unit 412, and in case that the weight value for the input node 21 corresponding to the input port 4101 virtually generated in Step S14 is positive, the transformation processing unit 52 connects the output from the input port 4101 directly to the adder unit 412. Further, in case that the weight value for the input node 21 corresponding to the input port 4101 virtually generated in Step S14 is negative, the transformation processing unit 52 sets an inverter 411, and connects the output from the input port 4101 through the inverter 411 to the adder unit 412 (S15: Setting of accumulation method).

Further, when the neuron cell circuit 4 in the second-type neural network is the one exemplified in FIG. 4, the transformation processing unit 52 performs the following process in Step S15, instead of the above-mentioned process.

In the example shown in FIG. 4, the transformation processing unit 52 configuring the neuron cell circuit 41s sets a pair of virtual adder units 412′a, 412′b, and a multiplication-addition unit 414. Then, in case that the weight value for the input node 21 corresponding to the input port 4101 virtually generated in Step S14 is positive, the transformation processing unit 52 connects the output from the input port 4101 directly to the adder unit 412′a. Whereas, in case that the weight value for the input node 21 corresponding to the input port 4101 virtually generated in Step S14 is negative, transformation processing unit 52 sets an inverter 411, and connects the output from the input port 4101 through the inverter 411 to the adder unit 412′b.

Then, the adder unit 412′a accumulates the data directly output from the input unit 410, and outputs P-data which is an accumulated value of data to be multiplied by a positive weight. Whereas, the adder unit 412′b accumulates the sign-inverted data output from the input unit 410 through the inverter 411, and outputs N-data which is an accumulated value of data to be multiplied by a negative weight.

The multiplication-addition unit 414 is set to multiply the P-data output from the adder unit 412′a by a predetermined weight value Wp (where Wp is a positive real number value), and multiply the N-data output from the adder unit 412′b by a predetermined weight value Wn (where Wn is a positive real number value, and can be the same value as Wp or can be a different value from Wp), add the value obtained by multiplying the P-data by the weight value Wp and the value obtained by multiplying the N-data by the weight value Wn, and output the resulting value. Thereby, the transformation processing unit 52 configuring the neuron cell circuit 41 in the example shown in FIG. 4 executes the setting of the accumulation method in Step S15.

The transformation processing unit 52 sets a virtual nonlinear function calculation unit 413. The output from the adder unit 412 or the output from the multiplication-addition unit 414, which are set in Step S15, is input to the nonlinear function calculation unit 413. The output from the nonlinear function calculation unit 413 is the output from the neuron cell circuit 41 selected in Step S12 (S16). The nonlinear function calculation unit 413 which is set here is a nonvolatile memory device having a memory address “a” storing a value which is obtained by multiplying a predetermined positive real number value A by a value f (a·Δq) which is an output value of the predetermined nonlinear function f corresponding the input value q(=a·Δq) (Δq has already been explained above, and thus, the explanation is not repeated and is omitted). Specific content of the nonlinear function f will be described later.

The transformation processing unit 52 repeatedly executes the processes from Step S13 to Step S16, with respect to each neuron cell circuit 41 of the to-be-processed layer virtually generated in Step S12 (namely, with respect to each output node 22 of the to-be-processed layer). Thereby, weight values are set for the group of neuron cell circuits 41 in the second-type neural network corresponding to the layers from the input layer 20a to the to-be-processed layer selected in Step S11 of the first-type neural network.

Then, if the corresponding output layer is not the output layer 20z (if there is a next layer), the transformation processing unit 52 returns to Step S12, selects the next layer as the corresponding output layer, and repeats processes from S13 to S16. Further, if the corresponding output layer is the output layer 20z, the transformation processing unit 52 sets, by machine learning, the nonlinear function calculated by the nonlinear function calculation unit 413 of each neuron cell circuit 41 that has been set (S17). Here, specifically, regarding a linear sum of a plurality of mutually different nonlinear functions fk (x) (k=1, 2 . . . ) (function obtained by linear combination of the mutually different nonlinear functions fk (x)):

$$f ( x ) = {\sum }_{k} {a}_{k} {f}_{k} ( x )$$

or a function of multiplying the linear sum by a predetermined positive real number A, the coefficient ak is set by machine learning, and thereby, machine leaning of the nonlinear function is performed. Here, the nonlinear function fk (x) is, for example, a step function, a sigmoid function, hyperbolic tangent, softsign, softplus, ReLU, Swish, and the like. At this time, the transformation processing unit 52 may set not only the coefficient ak, but also a parameter defining each nonlinear function fk (x), which is, for example, in case of a ReLU function:

$$f ( x ) = \{ \begin{matrix}α x , & x > 0 \\ 0 , & x \leq 0\end{matrix}$$

the value for α, together with the coefficient ak, by machine learning.

The transformation processing unit 52 of this example performs machine learning of the nonlinear function as below. Namely, the transformation processing unit 52 sequentially selects input data contained in the learning data which has been input, and inputs the selected data to the second-type neural network. Then, the transformation processing unit 52 obtains the output data from the second-type neural network at this time. The transformation processing unit 52 compares the output data contained in the learning data corresponding to the input data, with the output data obtained as above, and corrects the coefficient ak of the nonlinear function calculated by the nonlinear function calculation unit 413 of each neuron cell circuit 41 corresponding to the to-be-processed layer, and the parameter for each nonlinear function fk (x), using a method similar to backpropagation method. The transformation processing unit 52 executes this process with respect to each input data contained in the learning data, and sets the nonlinear function A·fk (x) (in the example shown in FIGS. 3A and 3B), or fk (x) (in the example shown in FIG. 4), calculated by the nonlinear function calculation unit 413 of each neuron cell circuit 41 (with the proviso that “A” represents a predetermined positive real number value).

After the nonlinear function is set, the transformation processing unit 52 may outputs information which represents representing a machine learning parameter for the second-type neural network generated by the above processes. For example, the transformation processing unit 52 associates each layer of the first-type neural network received by the receiving unit 51, with information identifying the relevant layer, and generates information by sequentially recording information specifying at least one neuron cell circuit 41 corresponding to the relevant layer. Here, as information for identifying the layer, a number for each layer is used, the number starting from “1” for the input layer 20a, and incrementing by “1” for the layer closer to the output layer 20z. Hereinbelow, the number (information for specifying the layer) is referred to as a layer number.

Further, the information for specifying each neuron cell circuit 41 is recorded in association with: the information for specifying at least one input port 4101 other than the input port 4101 demoved in the pruning process (Step S14); the information representing the presence/absence of the inverter 411, representing adder unit 412′ and the multiplication-addition unit 414, or representing the adder unit 412, corresponding to the output from each input port 4101; and the information representing the nonlinear function calculation unit 413 set in Step S17. Here, the information regarding the nonlinear function calculation unit includes information for specifying the calculation unit to which the value output from the adder unit 412 is input, and which calculates the nonlinear function determined in Step S17, and outputs an output value (calculation result of the nonlinear function) having a predetermined number of output bits.

Also, in response to, for example, instructions by a user, etc., the transformation processing unit 52 may perform a correction process mentioned below, with respect to at least a part of the neuron cell circuit 41, among the neuron cell circuits 41 corresponding to each node in each layer of the first-type neural network.

Namely, the transformation processing unit 52 may correct the number of bits for representing the output value of the nonlinear function calculated by the nonlinear function calculation unit 413 of the at least a part of the neuron cell circuit 41 (hereinbelow, referred to as a function output value) (S18), and output machine learning parameters for the second-type neural network. According to an example of the present aspect, transformation processing unit 52 reduces the number of bits for representing a function output value regarding the at least a part of the neuron cell circuit 41, to the number of bits equal to or more than the minimum number of bets determined by a predetermined method.

Here, the minimum number of bits may be different depending on the degree of closeness between the output layer 20z and the layer (corresponding layer), regarding the first-type neural network to which the output node corresponding to the neuron cell circuit 41 subjected to the reduction of the number of bits. As an example, the transformation processing unit 52 sets the minimum number of bits of the function output value of the neuron cell circuit 41 for the input layer 20a of the first-type neural network to 1 bit, and, sets the minimum number of bits for the intermediate layer 20b, 20c . . . to 1 bit, 4 bits, 4 bits . . . . That is, the closer the layer to the output layer 20z, the larger the minimum number of bits of the function output value of the neuron cell circuit 41 for each layer. Regarding the output layer 20z, preferably, the transformation processing unit 52 sets the minimum number of bits of the function output value of the neuron cell circuit 41 for the output layer 20 to be equal to the number of bits before the reduction (that is, reduction is not performed).

This is because that the latter (the layer closer to the output layer 20z) receives characteristics of the former, the characteristics are aggregated in the latter, and thus, the representability should be made large. Note that the setting of the number of bits of the function output value as above is an example, and the number of bits of the function output value can be determined by other method.

By this process in Step S18, the number of bits of the output value of the nonlinear function calculation unit subjected to the reduction, which is contained in the machine learning parameter of the second-type neural network, is changed.

Specifically, as exemplified in FIG. 7, the transformation processing unit 52 sequentially selects the respective layers of the first-type neural network starting from the input layer 20a, as a to-be-processed layer (S21). Regarding the neuron cell circuit 41 of the second-type neural network corresponding to the node which belongs to the to-be-processed layer, the transformation processing unit 52 examines whether or not the number of bits of the function output value thereof is larger than the minimum number of bits determined for the relevant neuron cell circuit 41 (S22), and when it is larger (S22: Yes), reduces the number of bits by “1” (S23).

Then, the transformation processing unit 52 sequentially inputs the input data contained in the learning data which has been input, to the second-type neural network which is to be processed, and obtains respectively corresponding output data (S24). The transformation processing unit 52 respectively compares each training data corresponding to the input data, with the output data of the second-type neural network corresponding thereto, and determines whether or not the error represented by the sum of absolute values of the respective differences is smaller than the predetermined threshold value (S25). Here, if the error is smaller than the predetermined threshold value (S25: Yes), the transformation processing unit 52 returns to Step S22 and continues the processes.

On the other hand, if the error is not smaller than the predetermined threshold value in Step S25 (S25: No), regarding the neuron cell circuit 41 of the second-type neural network corresponding to the node which belongs to the to-be-processed layer, the transformation processing unit 52 increments the number of bits of the function output value by “1” (S26), returns to Step S21, and if there is a next layer, selects the next layer as a to-be-processed layer and continues the processes. Whereas, if there is no next layer, the transformation processing unit 52 finishes the process of correcting the number of bits.

Further, in Step S22, if the number of bits of the function output value is not larger than the predetermined minimum number of bits for the neuron cell circuit 41 (S22: No), the transformation processing unit 52 returns to Step S21, and if there is a next layer, selects the next layer as a to-be-processed layer and continues the processes, whereas, if there is no next layer, finishes the process of correcting the number of bits.

In the above, the transformation processing unit 52 performs processes for the next layer after the process of Step S16. However, the present aspect is not limited thereto. The transformation processing unit 52 can repeat the processes from Step S13 to Step S17, for a plurality of times (processes shown by dotted lines in FIG. 6). Namely, the pruning process, the setting of the accumulation method in the neuron cell circuit 41 corresponding to each node of the to-be-processed layer, and the setting and learning of the nonlinear function, can be repeatedly executed for a predetermined number of times.

In this case, every time that the processes are repeated, the threshold value used in the pruning process is changed. For example, every time that the processes are repeated, the threshold value is increased by a predetermined ratio (for example, 10%). Thereby, every time that the processes are repeated, the number of input port 4101 reduced in the pruning process is increased. Further, when the repeat is executed, for the initial value of the nonlinear function in each neuron cell circuit 41 at the time of learning of the nonlinear function, the learning result of the nonlinear function of the previous execution is directly used.

The generation unit 53 generates production information for producing the second-type neural network, on the basis of the machine learning parameter of the second-type neural network, obtained after being transformed by the transformation processing unit 52.

As a specific example, the generation unit 53 refers to the information for specifying the neuron cell circuit 41 which is recorded in association with the layer number of each layer of the first-type neural network which is to be transformed, as machine learning parameters for the second-type neural network obtained by being transformed by the transformation processing unit 52. Then, in accordance with the information of the input port 4101 associated with the information which has been referred to, the information of the input port 4101 including the information for specifying the input port 4101 and the weight value for the relevant input port 4101 associated thereto, the generation unit 53 generates hardware designing information (which can be described by a predetermined hardware description language) for describing a hardware device corresponding to each input port 410, a hardware device for multiplying the data input to each input port 4101 by a corresponding weight value, and a hardware device corresponding to the adder unit 412 which accumulates the values multiplied by the weight values.

Further, on the basis of the information of the nonlinear function calculation unit 413 associated with the information which has been referred to, the generation unit 53 generates hardware designing information for mounting the nonlinear function calculation unit 413 to which the output from the adder unit 412 is input, and which outputs the output value of the nonlinear function corresponding to the input value.

Accordingly, the generation unit 53 generates the hardware designing information for the neuron cell circuit 41 recorded in association with each layer number, sequentially connects generated information, for example, in the order of the layer number, and outputs the connected information as information for producing the second-type neural network by actually using FPGA, etc. (production information).

The estimation unit 54 refers to the production information generated by the generation unit 53, and generates estimate information relating to at least one of the scale of the performance of the second-type neural network which is to be produced in accordance with the production information.

Specifically, the estimation unit 54 refers to the production information generated by the generation unit 53, and extracts the number of neuron cell circuits 41 recorded in association with each of the layer numbers (total neuron number), and an average of the number of input ports 4101 in each of the neuron cell circuit 41 (average synapse number).

Then, on the basis of the extracted information, the estimation unit 54 generates information such as the total sum of the number of neuron cell circuits 41 (total NC number), power consumption, time required for one inference (latency), and the like.

According to an example of the present aspect, the estimation unit 54 refers to result database (FIG. 8) which holds a plurality of records, each record including information regarding the total neuron number and the average synapse number for each layer number extracted from the production information of a hardware actually produced in the past, in association with information such as the total sum of the number of the neuron cell circuits 41 (total NC number) corresponding to the relevant layer number, power consumption, time required for one inference (latency) actually measured regarding an actually produced hardware.

Then, the estimation unit 54 compares the information of the total neuron number and the average synapse number for each layer number included in each record stored in the result database, with the information of the total neuron number and the average synapse number for each layer number in the production information of the estimation target hardware which is extracted with reference to the production information generated by the generation unit 53, and finds out the most similar record based on the comparison.

With respect to the record which has been found out for each layer, the estimation unit 54 respectively accumulates the information regarding the total NC number, the power consumption, and the latency, contained in the record, and generates estimate information.

The similarity between the information, in terms of the total neuron number and the average synapse number for each layer number can be evaluated by, for example, the similarity degree S:

S=α|NNa-NNb|+β|ASa-ASb|

wherein, NNa represents the total neuron number and Asa represents the average synapse number for each layer number regarding one of the comparison pair, and NNb represents the total neuron number and ASb represents the average synapse number for each layer number regarding the other of the comparison pair (with the proviso that α, β are predetermined positive constant, |X| represents an absolute value of X).

The output unit 55 outputs at least one of the production information generated by the generation unit 53, and the estimate information generated by the estimation unit 54.

### [Operation]

An operation example of the information processing apparatus 1 according to the present aspect will be explained. Hereinbelow, as an example, the first-type neural network which is to be transformed is shown in FIG. 9A. This first-type neural network comprises a convolution layer which is an input layer 20a receiving the input of image data, a pooling layer having intermediate layers 20b, 20c, 20d, another convolution layer, another pooling layer, a fully-connected layer which is an intermediate layer 20e before an output layer 20z, and the output layer 20z. This first-type neural network has been subjected to machine learning previously, with training data to perform predetermined estimation.

The information processing apparatus 1 receives a model of this first-type neural network (information for specifying each layer), and the machine learning parameter thereof. As exemplified in FIG. 9B, the machine learning parameter of the first-type neural network includes information regarding the weight between each input node 21-1, 21-2 . . . and each output node 22-1, 22-2, . . . , contained in each layer. In FIG. 9B, in order to make the explanation simple, only five input nodes are shown, but actually, there may be a larger number of input nodes. Also, in FIG. 9B, weight information for only one output node 22 is shown.

In FIG. 9B, the weights from the input nodes 21-1, 21-2, 21-3, 21-4, 21-5 to the output node 22 are W1=0.08, W2=−0.24, W3=−0.18, W4=0.14, W5=0.001 m, respectively.

The information processing apparatus 1 transforms the received machine learning parameters of the first-type neural network to the machine learning parameters of the second-type neural network. In the example below, the second-type neural network is the one exemplified in FIGS. 3A and 3B.

The information processing apparatus 1 receives a first-type neural network as a target for transformation, sequentially selects each of its layer as a to-be-processed layer, and virtually generates and initializes at least one neuron cell circuit 41 corresponding to the output node 22-j (j=1, 2 . . . , m) of the selected to-be-processed layer. As a specific example, the information processing apparatus 1 virtually sets input ports X1, X2 . . . , X5 corresponding to the input nodes 21-1, 21-2 . . . , 21-5, as neuron cell circuits 41 corresponding to FIG. 9B.

Then, regarding each neuron cell circuit 41, the information processing apparatus 1 obtains weight values for the input nodes 21-1, 21-2 . . . , 21-5 connected to the corresponding output node, and removes the input node 21 with the weight value having an absolute value lower than a predetermined threshold value (here, 0.01) (pruning process). In the example here, the input port X5 corresponding to the input node 21-5 which corresponds to the weight W5 is removed.

Regarding the remaining input ports X1, X2, X3, X4, the information processing apparatus 1 refers to the weights from the corresponding input nodes 21-1, 21-2, 21-3, 21-4 to the output node 22, and based on the sign of each weight, sets whether or not the sign of the input data should be inverted. Namely, if the sign of the weight for the corresponding input node 21 is negative, the information processing apparatus 1 sets the inverter 411 for inverting the sign of data of the input port Xi corresponding to the relevant input node. In the example here, the inverters 411 are set to invert the signs of the data input to the input ports X2, X3 (FIG. 10).

Further, the information processing apparatus 1 sets the nonlinear function to be calculated by the nonlinear function calculation unit 413 of each neuron cell circuit 41, by machine learning. The input to the nonlinear function calculation unit 413 is an output from the adder unit 412 in the corresponding neuron cell circuit 41. Namely, in the example shown in FIG. 10, the input to the nonlinear function calculation unit 413 is a result obtained by accumulating the data input to the input ports X1, X4, and the data input to the input ports X2, X3 and subjected to the sign inversion by the corresponding inverters 411.

According to an example of the present aspect, for the purpose of the machine learning of this nonlinear function, regarding a function obtained by linear combination of a plurality of mutually different nonlinear functions fk (x) (k=1, 2 . . . ):

$$f ( x ) = {\sum }_{k} {a}_{k} {f}_{k} ( x )$$

at least the coefficient ak is set by machine learning. Here, the nonlinear function fk (x) is, for example, a step function, a sigmoid function, hyperbolic tangent, softsign, softplus, ReLU, Swish, and the like. As mentioned above, the parameter for defining each nonlinear function fk (x) can also be machine-learned, as well as the above coefficient. Actually, in this example, the nonlinear function to be calculated by the nonlinear function calculation unit 413 is a value obtained by multiplying the above function f (x) obtained by the linear combination the plurality of mutually different nonlinear functions fk (x) (k=1, 2 . . . ), by a positive real number value A.

Further, as a state prior to the machine learning (initial state), the information processing apparatus 1 may set, regarding each neuron cell circuit 41, the coefficient ak for the nonlinear function fk (x) which is the same as the nonlinear function to be calculated by the output node 22 of the corresponding first-type neural network, to be larger than the coefficients ak for other nonlinear functions fk (x).

Specifically, the coefficient ak for the nonlinear function fk (x) which is the same as the nonlinear function to be calculated by the output node 22 of the corresponding first-type neural network is set to a value n which is smaller than “1” but sufficiently close to “1”, whereas the coefficients ak for other nonlinear functions fk (x) are set to a value obtained by dividing n by n, n being the number of other nonlinear functions fk (in this example, the total sum of the coefficients ak becomes “1”).

The information processing apparatus 1 uses the separately prepared learning data (data including input values in association with corresponding output data (training data) of the neural network, which should be truth), and sequentially inputs the input data included in this learning data to the virtual set second-type neural network.

Every time that the input data is input, the information processing apparatus 1 compares the output value output from the tentatively set second-type neural network, with the training data included in the learning data corresponding to the input data that has been input. On the basis of this comparison, the information processing apparatus 1 corrects the above-mentioned coefficient ak of the nonlinear function calculated by the nonlinear function calculation unit of each neuron cell circuit 41, by a backpropagation method.

Accordingly, the information processing apparatus 1 executes a process to set a weight value corresponding to the input port 4101 by fixing the nonlinear function, and a process to set a nonlinear function by fixing the weight value, and obtains machine learning parameters of the second-type neural network.

The information processing apparatus 1 generates production information for producing each neuron cell circuit 41 set as above, as a hardware.

Further, the information processing apparatus 1 compares the information regarding the total neuron number and the average synapse number for each layer number included in each record stored in the result database with reference to the result database based on the production information of hardware actually produced in the past, as exemplified in FIG. 8, with the information regarding the total neuron number and the average synapse number for each layer number of the production information of an estimation target hardware, extracted with reference to the generated production information, and finds out the most similar record based on the comparison.

Then, the information processing apparatus 1 accumulates the information regarding the total NC number, the power consumption, and the latency, respectively, included in the record which has been found out for each layer number, generates the estimate information, and resents the generated estimate information to a user.

The user of this information processing apparatus 1 refers to the presented estimate information. For the purpose of, for example, reducing the power consumption, latency, etc., the user may further instruct the information processing apparatus 1 to reduce the number bits for expressing the function output value which is the output value from the nonlinear function calculation unit of each neuron cell circuit 41.

The information processing apparatus 1 receives the instructions, and corrects the number bits for expressing the function output value which is the output value from the nonlinear function calculation unit of at least one neuron cell circuit 41 contained in the second-type neural network obtained by transformation. Specifically, regarding the layer of the first-type neural network to which the output node corresponding to the neuron cell circuit 41 with the reduced number of bits belongs, if the layer is the input layer 20a, the information processing apparatus 1 sets the minimum number of bits of the function output value to 1 bit. Subsequently, information processing apparatus 1 sets the minimum number of bits of the function output values of the neuron cell circuit 41 corresponding to the intermediate layers 20b, 20c . . . to 1 bit, 4 bits, 4 bits . . . , so that the closer to the output layer 20z, the larger the value.

The information processing apparatus 1 uses the learning data, and corrects the number of bits of the function output value which is the output value from the nonlinear function calculation unit of each neuron cell circuit 41, so that the difference between the output value in response to the input of the input data contained in the learning data and the corresponding training data is smaller than a predetermined difference, and the output value is equal to or more than the minimum number but is the smallest number of bits in the range.

Then, the information processing apparatus 1 generates the production information for generating each neuron cell circuit 41 after the correction as a hardware, and generates the estimate information by accumulating information of the total NC number, the power consumption, and the latency, respectively, for each of the layer numbers after the correction, with reference to the result database, and present the generated information to the user.

### [Repeat of Pruning and Nonlinear Function Learning]

Further, the information processing apparatus 1 may repeat the processes from the pruning process, again, in response to the instruction by a user, etc. Namely, regarding the first-type neural network which is the transformation target, the information processing apparatus 1 sequentially selects each layer as a to-be-processed layer again, and executes the following processes for each neuron cell circuit 41 corresponding to the output node 22-j (j=1, 2 . . . , m) of the selected to-be-processed layer.

Namely, regarding each neuron cell circuit 41, the information processing apparatus 1 obtains weight values for the input nodes 21-1, 21-2 . . . , 21-5 connected to the corresponding output node 22. Among the obtained weight values, if the absolute value thereof is smaller than a predetermined threshold value, the input node 21 with such a weight value is removed. Here, the threshold value is set to be larger than the threshold value used in the previous pruning process. As an example, if the threshold value used in the previous pruning process is 0.01, the threshold value for the current pruning process is set to, for example, 0.15.

As mentioned above, in an example where the weights from the input nodes 21-1, 21-2, 21-3, 21-4, 21-5 to the output node 22 are W1=0.08, W2=−0.24, W3=−0.18, W4=0.14, W5=0.001, respectively, the input port X5 which corresponds to the input node 21-5 corresponding to the weight W5, and the input port X4 which corresponds to input node 21-4 corresponding to the weight W4, are removed.

Then, regarding the remaining input ports X1, X2, X3, the information processing apparatus 1 refers to the weight from the corresponding input nodes 21-1, 21-2, 21-3 to the output node 22, and sets the weight value to Wp, Wm, Wm as weight values by which the data input from respective input nodes are multiplied.

Next, the information processing apparatus 1 sets the nonlinear function calculated by the nonlinear function calculation unit of each neuron cell circuit 41 by machine learning. At this time, the previous learning result of the nonlinear function is directly used as the initial value for each nonlinear function.

According to this process, the number of input ports 4101, namely, the average synapse number can be reduced. Further, regarding the neuron cell circuit 41 from which all input ports 4101 are removed by the pruning process, the neuron cell circuit 41 itself is removed, and replaced with a ground terminal, etc. In this case, the total neuron number is also reduced.

As an example, in the operation of transforming a deep learning neural network exemplified in FIG. 9A, the information processing apparatus 1 reduces the number of input ports 4101 of the neuron cell circuit 41 corresponding to the convolution layer which is the input layer 20a receiving the input of image data, to 30%. Further, the information processing apparatus 1 sets the threshold value in each pruning process so that the closer to the fully-connected layer, the larger the reduction amount. For example, the reduction is performed such that: the number of input ports 4101 of the neuron cell circuit 41 corresponding to the intermediate layer 20b (pooling layer) is reduced to 25%;

the number of input ports 4101 of the neuron cell circuit 41 corresponding to the intermediate layer 20c (convolution layer) is reduced to 10%; and the number of input ports 4101 of the neuron cell circuit 41 corresponding to the intermediate layer 20d (pooling layer) is reduced to 10%.

Then, the information processing apparatus 1 reduces the number of input ports 4101 of the neuron cell circuit 41 corresponding to the fully-connected layer which is the intermediate layer 20e before the output layer 20z, to 40%. Thereby, the circuit scale is reduced.

According to an example of the present aspect, the user can adjust the threshold value and the number of repetitions of the pruning process, the number of bits of the output from the nonlinear function of each neuron cell circuit 41, and the like, obtain estimate information thereof, respectively, and repeat designing to satisfy desired conditions. Regarding each machine learning parameter for the second-type neural network obtained by repeating the pruning process, etc., the information processing apparatus 1 may obtain the accuracy of the output value (accuracy of estimation) by using a predetermined learning data, and present the accuracy by including the accuracy in the estimate information.

### [Explanation of Numerals]

1 information processing apparatus, 11 control unit, 12 storage unit, 13 operation unit, 14 display unit, 15 input/output unit, 21 input node, 22 output node, 30 input circuit unit, 40 machine learning circuit, 41 neuron cell circuit, 50 output circuit unit, 51 receiving unit, 52 transformation processing unit, 53 generation unit, 54 estimation unit, 55 output unit, 221 product-sum calculation unit, 222 nonlinear function calculation unit, 410 input unit, 411 inverter, 412, 412′ adder unit, 413 nonlinear function calculation unit, 414 multiplication-addition unit, 4101 input port.

1.-10. (canceled)

11. An information processing apparatus comprising:
a receiving device which receives an input of a machine learning parameter for a first-type neural network which has machine-learned an output corresponding to a predetermined input;
a transformation processing device which transforms the received machine learning parameter for the first-type neural network to a machine learning parameter for a second-type neural network which is a different type neural network from the first-type neural network;
a generation device which generates production information for producing the second-type neural network, on the basis of the transformed machine learning parameter;
an estimation device which generates estimate information regarding at least one of a scale and performance, relating to the second-type neural network produced in accordance with the production information; and
an output device which outputs the production information and the estimate information.

12. An information processing apparatus according to claim 11, wherein
the first-type neural network is a deep learning neural network,
the transformation processing device is a transformation processing device which virtually sets a neuron cell circuit for an output node of each layer of the first-type neural network,
at least one of the set neuron cell circuits is provided with an input port, an inverter, an adder, and a nonlinear calculation unit, and the inverter is an inverter which invers a sign of the input data,
when the transformation processing device sets each of the neuron cell circuits, on the basis of weight information for an input node connected to the output node of the corresponding first-type neural network, the transformation processing device arranges an input port corresponding to the input node, and sets each of the arranged input port so that the data input to the input port is directly output, or the data input to the input port is output after being inverted by the provided invertor,
the transformation processing device sets the adder so that the adder accumulates the directly output data or the data output through the inverter, and
the transformation processing device sets the nonlinear calculation unit so that the nonlinear calculation unit receives the accumulated value output from the adder, and outputs a function value of a predetermined nonlinear function corresponding to the received accumulated value.

13. An information processing apparatus according to claim 12, wherein
when the transformation processing device sets each of the neuron cell circuits, the transformation processing device executes a pruning process by which, an input port is set only when the input port corresponds to the input node with weight information larger than a predetermined threshold value, among the input nodes connected to the output node corresponding to the first-type neural network.

14. An information processing apparatus according to claim 13, wherein
the first-type neural network is a deep learning neural network with the first layer as an input layer, and the N-th layer (N being an integer of 3 or more) as an output layer, and
when the transformation processing device sets the neuron cell circuit corresponding to the output node of the i-th layer (i being an integer of 1≤i≤N) of the first-type neural network layer, the transformation processing device controls so that when a value “i” representing a depth of the layer is equal to or lower than at least a predetermined integer value J (with the proviso that 1≤J≤N), the larger the value “i”, the smaller the number of input ports set by the pruning process.

15. An information processing apparatus according to claim 12, wherein
when the transformation processing device sets each of the neuron cell circuits, the transformation processing device sets a weight value corresponding to the input port set for each neuron cell circuit, and thereafter, sets a nonlinear function calculated by the nonlinear calculation unit set for each neuron cell circuit by a machine learning process using a predetermined training information.

16. An information processing apparatus according to claim 15, wherein
when the transformation processing device performs machine learning of the nonlinear function calculated by the nonlinear calculation unit, the transformation processing device sets the nonlinear function as a linear sum of a predetermined plurality of types of nonlinear functions, and sets a coefficient value for multiplying the nonlinear function of each type by machine learning.

17. An information processing apparatus according to claim 12 wherein
when the transformation processing device sets each of the neuron cell circuits, the transformation processing device sets the number of bits of the output from the nonlinear calculation unit of the neuron cell circuit to be set, corresponding to the position of a layer in the first-type neural network which includes the output node corresponding to the neuron cell circuit to be set.

18. An information processing apparatus according to claim 12, wherein
the production information generated by the generation device is production information for producing each of the neuron cell circuits set by the transformation processing device as a hardware, and is expressed by a hardware description language.

19. An information processing apparatus according to claim 12, further comprising a device which accesses a result database containing information relating to at least one of a scale and performance of second-type neural networks produced in the past, in association with the number of neuron cell circuits contained in the second-type neural network and the number of input ports contained in the neuron cell circuit, wherein
the estimation device uses the number of neuron cell circuits set by the transformation processing device and the number of input ports contained in the neuron cell circuit, acquires information relating to at least one of the scale and performance of the second-type neural network which is determined as similar to the neuron cell circuits set by the transformation processing device, among the second-type neural networks produced in the past and stored in the result database, and outputs the acquired information as estimate information.

20. A computer readable and non-transitory recording medium which stores a program by which a computer functions as:
a receiving device which receives an input of a machine learning parameter for a first-type neural network which has machine-learned an output corresponding to a predetermined input;
a transformation processing device which transforms the received machine learning parameter for the first-type neural network to a machine learning parameter for a second-type neural network which is a different type neural network from the first-type neural network;
a generation device which generates production information for producing the second-type neural network, on the basis of the transformed machine learning parameter;
an estimation device which generates estimate information regarding at least one of a scale and performance, relating to the second-type neural network produced in accordance with the production information; and
an output device which outputs the production information and the estimate information.
